(19) United States
(12) Patent Application Publication
(10) Pub. No.: US 2021/0033959 A1
(43) Pub. Date: Feb. 4, 2021

(54) EXTREME ULTRAVIOLET PHOTOMASK MANUFACTURING METHOD AND SEMICONDUCTOR DEVICE FABRICATION METHOD INCLUDING THE SAME

(71) Applicant: Samsung Electronics Co., Ltd., Suwon-si (KR)

(72) Inventors: Hakseung Han, Hwaseong-si (KR); Sanguk Park, Yongin-si (KR); Jongju Park, Hwaseong-si (KR); Raewon Yi, Suwon-si (KR)

(21) Appl. No.: 15/931,709

(22) Filed: May 14, 2020

(30) Foreign Application Priority Data
Aug. 1, 2019 (KR) 10-2019-0093838
Nov. 4, 2019 (KR) 10-2019-0139647

(51) Int. Cl. G03F 1/24; G03F 1/60; G03F 1/58; H01L 21/308; G03F 1/72; G03F 7/20

(52) U.S. Cl. CPC G03F 1/24; G03F 1/60; G03F 7/70033; H01L 21/3086; G03F 1/72; G03F 1/58

(57) ABSTRACT

Disclosed are photomask manufacturing methods and semiconductor device fabrication methods. The photomask manufacturing method includes forming a reflective layer on a mask substrate having an image region and an edge region surrounding the image region, forming an absorption pattern on the reflective layer, forming a black border by irradiating a first laser beam to the reflective layer and the absorption pattern on the edge region, using a photomask having the black border to provide a test substrate with an extreme ultraviolet (EUV) beam to form a test pattern, obtaining a critical dimension correction map of the test pattern, and using the critical dimension correction map to irradiate a second laser beam to the reflective layer on a portion of the image region to form an annealed region that is thicker than the black border.

### CROSS-REFERENCE TO RELATED APPLICATIONS

This U.S. nonprovisional application claims priority under 35 U.S.C § 119 to Korean Patent Application Nos. 10-2019-0093838 filed on Aug. 1, 2019 and 10-2019-0139647 filed on Nov. 4, 2019, in the Korean Intellectual Property Office, the disclosures of each of which are hereby incorporated by reference in their entirety.

### FIELD

The present inventive concepts relate to semiconductor device fabrication methods, and more particularly, to extreme ultraviolet (EUV) photomask manufacturing methods and semiconductor device fabrication methods including the same.

### BACKGROUND

With advances in information technology, research and development for highly-integrated semiconductor devices are actively being conducted. Integration of semiconductor devices may be determined by the wavelength of a light source for photolithography. The light source may include an excimer laser source, such as I-line, G-line, KrF, and ArF, and an extreme ultraviolet (EUV) light source whose wavelength is shorter than that of an excimer laser source. The power or energy of an EUV light source may be significantly greater than that of an excimer laser source.

### SUMMARY

Some example embodiments of the present inventive concepts provide a photomask manufacturing method that improves critical dimension uniformity and semiconductor device fabrication methods including the same.

According to some embodiments of the present inventive concepts, a photomask manufacturing method may comprise: forming a reflective layer on a mask substrate that has an image region and an edge region surrounding the image region; forming an absorption pattern on the reflective layer; irradiating a first laser beam to the reflective layer and the absorption pattern on the edge region to form a black border; providing an extreme ultraviolet (EUV) beam to a test substrate using a photomask having the black border to form a test pattern; obtaining a critical dimension correction map of the test pattern; and irradiating a second laser beam to the reflective layer on a portion of the image region using the critical dimension correction map to form an annealed region that is thicker than the black border.

According to some embodiments of the present inventive concepts, a photomask manufacturing method may comprise: forming a reflective layer on a mask substrate that has an image region and an edge region surrounding the image region; forming an absorption pattern on the mask substrate; irradiating a first laser beam to the absorption pattern and the reflective layer on the edge region to form a first annealed region; and irradiating a second laser beam to the reflective layer on the image region to form a second annealed region that is thicker than the first annealed region.

According to some embodiments of the present inventive concepts, a semiconductor device fabrication method may comprise: manufacturing a photomask; forming a photoresist pattern on a substrate using the photomask; and etching a portion of the substrate using the photoresist pattern as an etching mask. The manufacturing of the photomask includes: forming a reflective layer on a mask substrate that has an image region and an edge region surrounding the image region; forming an absorption pattern on the reflective layer; irradiating a first laser beam to the reflective layer and the absorption pattern on the edge region to form a black border; providing an extreme ultraviolet (EUV) beam to a test substrate using the photomask having the black border to form a test pattern; obtaining a critical dimension correction map of the test pattern; and irradiating a second laser beam to the reflective layer on a portion of the image region using the critical dimension correction map to form an annealed region that is thicker than the black border.

### BRIEF DESCRIPTION OF THE DRAWINGS

Embodiments of the present inventive concepts are described below with reference to the following figures, in which:

FIG. 1 illustrates a flow chart showing a semiconductor device fabrication method according to some embodiments of the present inventive concepts;

FIG. 2 illustrates a flow chart showing an example of a photomask manufacturing step of FIG. 1;

FIGS. 3 to 7 illustrate cross-sectional views showing photomask manufacturing processes;

FIG. 8 illustrates a plan view showing an example of image and edge regions of a mask substrate in FIG. 3;

FIG. 9 illustrates a schematic diagram showing an example of an exposure apparatus on which the photomask of FIG. 7 is loaded;

FIG. 10 illustrates a cross-sectional view showing an example of a test pattern formed on a test substrate of FIG. 9;

FIG. 11 illustrates a cross-sectional view showing an example of an inspection apparatus that investigates the test pattern of FIG. 10;

FIG. 12 illustrates a plan view showing a critical dimension correction map of the test pattern of FIG. 11;

FIG. 13 illustrates a cross-sectional view showing an example of a second laser apparatus that anneals a reflective layer on an image region of FIG. 5;

FIG. 14 illustrates a graph showing a first absorptance of a reflective layer based on wavelength of a second laser beam of FIG. 13 and also showing second absorptances of a structure in which a mask pattern and a reflective layer are stacked;

FIG. 15 illustrates a cross-sectional view showing that a first laser beam of a first laser apparatus of FIG. 7 forms an inclined surface of a reflective layer on an annealing region;

FIG. 16 illustrates a cross-sectional view showing an example of a second laser apparatus that irradiates a second laser beam to a reflective layer of FIG. 3;

FIG. 17 illustrates a graph showing third absorptances of a second laser beam provided to a bottom surface of a reflective layer in FIG. 3;

FIG. 18 illustrates an exposure apparatus on which a photomask having an annealing region of FIG. 13; and

FIGS. 19 and 20 illustrate cross-sectional view showing processes performed on a substrate of FIG. 18.

### DETAILED DESCRIPTION OF EMBODIMENTS

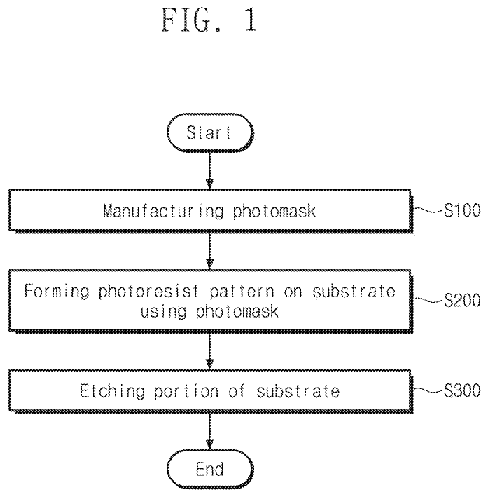

FIG. 1 is a flowchart illustrating an example of a semiconductor device fabrication method according to some embodiments of the present inventive concepts.

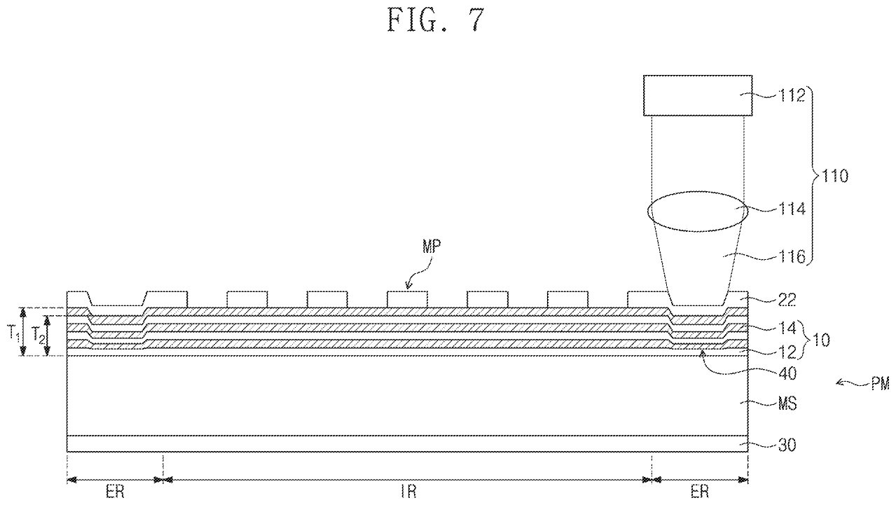

Referring to FIG. 1, a mask manufacturing apparatus may manufacture a photomask PM of FIG. 7 (S100). For example, the photomask PM may include a reflective photomask. The photomask PM may include, for example, an extreme ultraviolet (EUV) photomask.

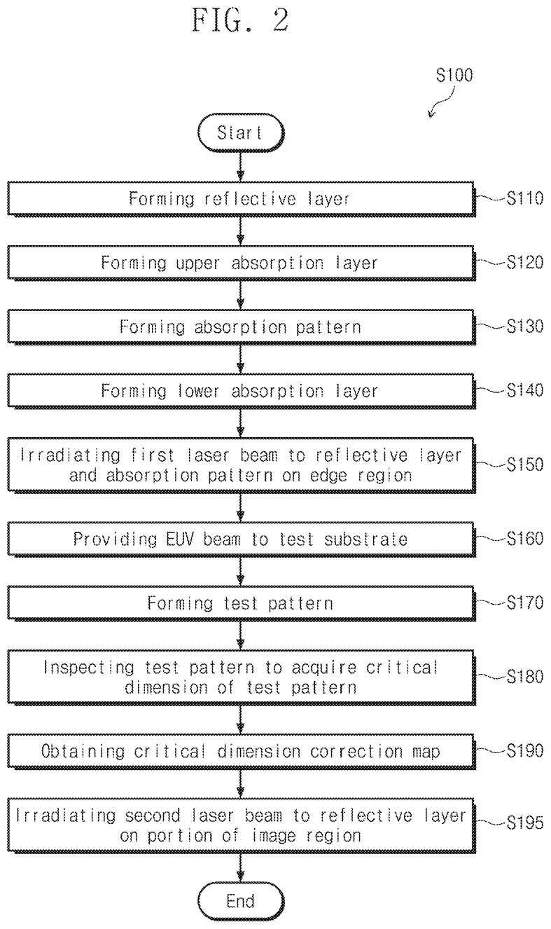

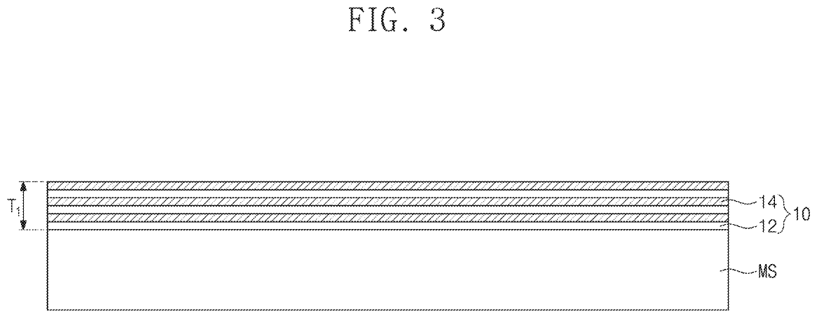

FIG. 2 is a flowchart illustrating an example of the photomask manufacturing step S100 of FIG. 1. FIGS. 3 to 7 illustrate cross-sectional views showing photomask manufacturing processes.

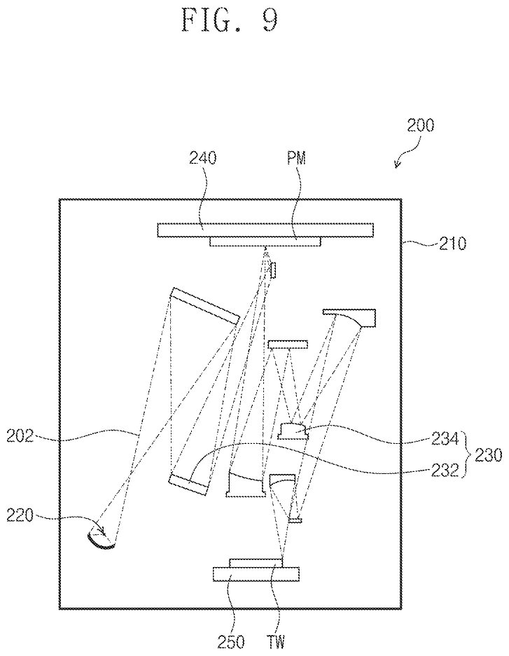

Referring to FIGS. 2 and 3, a thin-layer deposition apparatus may form a reflective layer 10 on a mask substrate MS (S110). The mask substrate MS may include, for example, quartz or glass. The reflective layer 10 may be, for example, an extreme ultraviolet (EUV) reflective layer. The reflective layer 10 may reflect an extreme ultraviolet (EUV) beam (see 202 of FIG. 9). The reflective layer 10 may have a first thickness T1, e.g., of about 280 nm. The terms “first,” “second,” etc., may be used herein to distinguish one element or characteristic from another. The reflective layer 10 may be formed by atomic layer deposition or chemical vapor deposition. The reflective layer 10 may include, for example, a semiconductor layer 12 and a metal layer 14. The semiconductor layer 12 and the metal layer 14 may be formed alternately with each other. A pair of the semiconductor layer 12 and the metal layer 14 may be stacked, e.g., about 40 times. The pair of the semiconductor layer 12 and the metal layer 14 may have a thickness, e.g., of about 7 nm. The semiconductor layer 12 may include a silicon layer. The metal layer 14 may include a molybdenum layer.

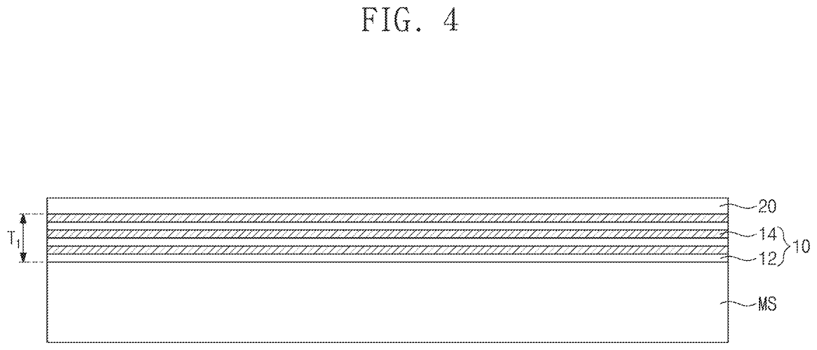

Referring to FIGS. 2 and 4, the thin-layer deposition apparatus may form an upper absorption layer 20 (S120). The upper absorption layer 20 may include metal nitride. For example, the upper absorption layer 20 may include tantalum boron nitride (TaBN). For another example, the upper absorption layer 20 may include chromium nitride, but the present inventive concepts are not limited thereto. The upper absorption layer 20 may have a thickness of about 50 nm to about 70 nm.

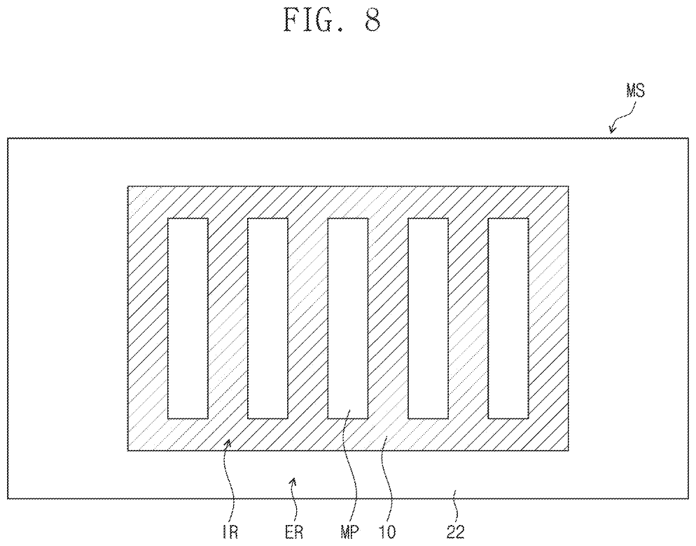

FIG. 8 shows an example of an image region IR and an edge region ER of the mask substrate MS of FIG. 3.

Referring to FIGS. 2, 5, and 8, an electron beam lithography apparatus 24 may use a first electron beam 26 to partially remove the upper absorption layer 20 to form an absorption pattern 22 (S130). For example, the mask substrate MS may have the edge region ER and the image region IR. The image region IR may be disposed on a center or central region of the mask substrate MS. The edge region ER may surround the image region IR and may lie on an edge of the mask substrate MS. The absorption pattern 22 on the edge region ER may shield the reflective layer 10. The absorption pattern 22 on the image region IR may be defined as a mask pattern MP and/or an image pattern that partially expose the reflective layer 10.

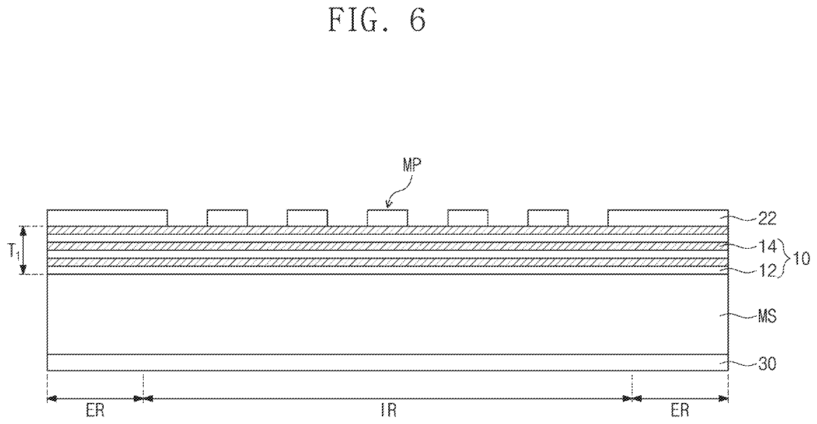

Referring to FIGS. 2 and 6, the thin-layer deposition apparatus may form a lower absorption layer 30 on a bottom surface of the mask substrate MS (S140). The lower absorption layer 30 may be the same material as the upper absorption layer 20. For example, the lower absorption layer 30 may include tantalum boron nitride (TaBN) or chromium nitride (CrN). The lower absorption layer 30 may have a thickness of about 50 nm to about 70 nm. Alternatively, the formation of the lower absorption layer 30 may be followed by the formation of the reflective layer 10. The formation of the lower absorption layer 30 may be followed by the formation of the upper absorption layer 20, but the present inventive concepts are not limited thereto.

Referring to FIGS. 2 and 7, a first laser apparatus 110 may irradiate a first laser beam 116 onto the reflective layer 10 and the absorption pattern 22 on the edge region ER of the mask substrate MS, thereby forming a black border 40 (S150). For example, the first laser apparatus 110 may include a first light source 112 and a first optical system 114. The first light source 112 may generate the first laser beam 116. The first laser beam 116 may be an infrared laser beam. The first laser beam 116 may have a first wavelength, e.g., of about 980 nm. The first optical system 114 may be disposed between the first light source 112 and the mask substrate MS. The first optical system 114 may include a convex lens. The first optical system 114 may concentrate the first laser beam 116 on the edge region ER of the mask substrate MS, and thus the black border 40 may be formed. The black border 40 may be a first annealing region of the reflective layer 10. When viewed in plan view, the black border 40 may surround the mask pattern MP on the image region IR of the photomask PM. The black border 40 may be an edge portion of the photomask PM. The black border 40 may cause reflective layer 10 to have a reduced reflectance or an increased absorptance with respect to the EUV beam 202. For example, the black border 40 may have a reflectance of 0% with respect to the EUV beam 202 and an absorptance of 100% with respect to the EUV beam 202. The reflective layer 10 in the black border 40 may have a second thickness T2 less than the first thickness T1. For example, the reflective layer 10 in the black border 40 may have a second thickness T2 of about 100 nm to about 200 nm.

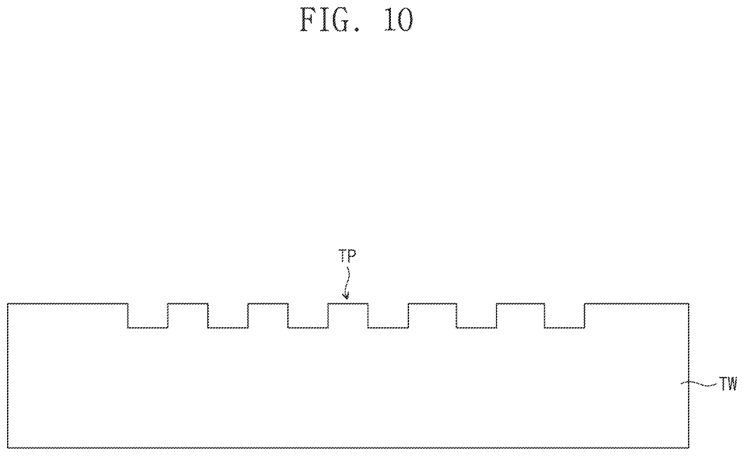

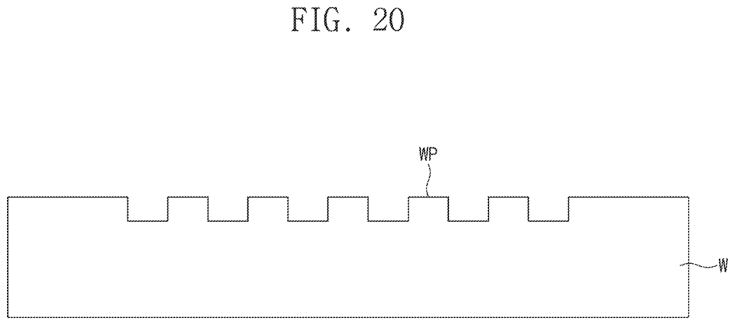

The following will describe a method in which the photomask PM is used to acquire a critical dimension of a test pattern (see TP of FIG. 10) to obtain critical dimension uniformity, and in which based on the obtained critical dimension uniformity, the reflective layer 10 on a portion of the image region IR is annealed to improve critical dimension uniformity of a substrate pattern (see WP of FIG. 20).

FIG. 9 shows an example of an exposure apparatus 200 on which the photomask PM of FIG. 7 is loaded.

Referring to FIGS. 2 and 9, the exposure apparatus 200 may use the photomask PM to provide the EUV beam 202 to a test substrate TW (S160). The exposure apparatus 200 may be, for example, an extreme ultraviolet (EUV) exposure apparatus. For example, the exposure apparatus 200 may include a chamber 210, an extreme ultraviolet (EUV) source 220, a second optical system 230, a mask stage 240, and a substrate stage 250.

The chamber 210 may provide the test substrate TW and the photomask PM with a space isolated from the external environment. The chamber 210 may have a vacuum pressure, for example, ranging from about 1×10⁻⁴ Torr to about 1×10⁻⁶ Torr.

The EUV source 220 may be disposed in one side of the chamber 210. The EUV source 220 may generate the EUV beam 202. The EUV beam 202 may be a plasma beam. For example, the EUV source 220 may provide optical pumping or pump light to liquid metal droplets of tin (Sn), xenon (Xe) gases, titanium (Ti), or lithium (Li), thereby generating the EUV beam 202. The EUV beam 202 may have a wavelength, e.g., of about 13.5 nm. The EUV source 220 may provide the second optical system 230 with the EUV beam 202.

The second optical system 230 may be disposed between the mask stage 240 and the substrate stage 250. The second optical system 230 may provide the EUV beam 202 sequentially to the photomask PM and the test substrate TW. The second optical system 230 may include illumination mirrors 232 and projection minors 234. The illumination mirrors 232 may be disposed between the EUV source 220 and the mask stage 240. The illumination mirrors 232 may provide the photomask PM with the EUV beam 202. The projection minors 234 may receive the EUV beam 202 reflected from the reflective layer 10 on the image region IR of the photomask PM. The projection minors 234 may be disposed between the mask stage 240 and the substrate stage 250. The projection minors 234 may reflect the EUV beam 202 toward the test substrate TW.

The mask stage 240 may be installed in an upper portion of the chamber 210. The mask stage 240 may be disposed between the illumination mirrors 232 and the projection mirrors 234, i.e., from the perspective of the EUV beam 202. The mask stage 240 may hold the photomask PM. The mask stage 240 may drive the photomask PM to move in a direction parallel to the mask substrate MS in an exposure process employing the EUV beam 202.

The substrate stage 250 may be installed in a lower portion of the chamber 210. The substrate stage 250 may receive and hold the test substrate TW. The substrate stage 250 and the mask stage 240 may be parallel to each other. When the mask stage 240 drives the photomask PM to move, the substrate stage 250 may drive the test substrate TW to move in a direction the same as or opposite to the moving direction of the photomask PM, thereby scanning the EUV beam 202 on the test substrate TW. The EUV beam 202 may photosensitize a photoresist or otherwise irradiate a photosensitive material layer on the test substrate TW, based on the mask pattern MP. A spinner apparatus (not shown) may develop the photosensitized photoresist into a photoresist pattern.

FIG. 10 shows an example of a test pattern TP formed on the test substrate TW of FIG. 9.

Referring to FIGS. 2 and 10, an etch apparatus may use the photoresist pattern as an etching mask to etch the test substrate TW to form the test pattern TP (S170). The photoresist pattern may be removed. The test pattern TP may be a protruding embossing pattern. Alternatively, the test pattern TP may be a trench pattern.

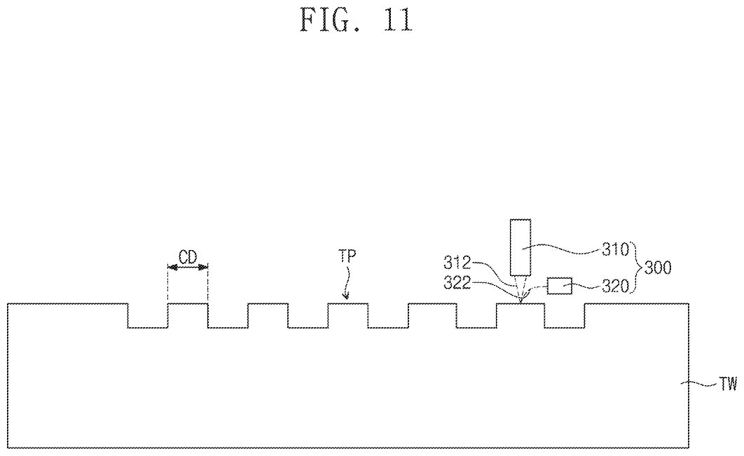

FIG. 11 shows an example of an inspection apparatus 300 that inspects the test pattern TP of FIG. 10.

Referring to FIGS. 2 and 11, the inspection apparatus 300 may inspect the test pattern TP to obtain a critical dimension CD of the test pattern TP (S180). The inspection apparatus 300 may be a scanning electron microscope (SEM). For example, the inspection apparatus 300 may include an electron gun 310 and a detector 320. The electron gun 310 may provide a second electron beam 312 onto the test substrate TW. The second electron beam 312 may release a secondary electron 322 from the test substrate TW. The detector 320 may detect the secondary electron 322 to obtain an image of the test pattern TP. The test pattern TP may be compared with a reference pattern or a target pattern. The detector 320 may measure the critical dimension CD of the test pattern TP. The critical dimension CD may be differently measured based on the test pattern TP. The critical dimension CD measured from the test pattern TP may be compared with a critical dimension of a reference pattern.

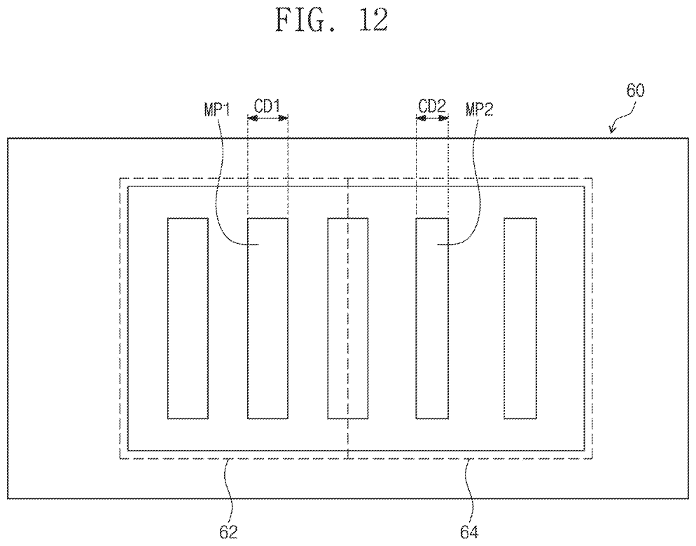

FIG. 12 shows a critical dimension correction map 60 of the test pattern TP of FIG. 11.

Referring to FIGS. 2 and 12, the inspection apparatus 300 may use the measured critical dimension CD to obtain the critical dimension correction map 60 (S190). The critical dimension correction map 60 may represent a difference in critical dimension between the test pattern TP and a reference pattern. For example, in the critical dimension correction map 60, the difference in critical dimension between the test pattern TP and a reference pattern may be expressed in proportion to a magnification between the test pattern TP and the mask pattern MP. When the mask pattern MP has a magnification four times larger than the test pattern TP, the critical dimension correction map 60 may represent the critical dimension difference four times greater. When the mask pattern MP and the test pattern TP have the same magnification, the critical dimension correction map 60 may represent the critical dimension difference without magnification. The following will discuss an example in which the mask pattern MP and the test pattern TP have the same magnification and in which the critical dimension correction map 60 has no difference in critical dimension.

The critical dimension correction map 60 may have, for example, a non-correction region 62 and a correction region 64. The non-correction region 62 may be an area where the mask pattern MP and the test pattern TP are coincident with each other within tolerance limits. A first mask pattern MP1 may be expressed in the non-correction region 62. A first critical dimension CD1 of the first mask pattern MP1 in the non-correction region 62 may coincide within tolerance limits with the critical dimension CD of the test pattern TP. The correction region 64 may be an area where the mask pattern MP and the test pattern TP are not coincident with each other within tolerance limits. A second mask pattern MP2 may be expressed in the correction region 64. A second critical dimension CD2 of the second mask pattern MP2 in the correction region 64 may not coincide within tolerance limits with the critical dimension CD of the test pattern TP. The second critical dimension CD2 may be different from the first critical dimension CD1. For example, the second critical dimension CD2 may be less than the first critical dimension CD1. The first and second critical dimensions CD1 and CD2 may have a critical dimension difference (e.g., CD1-CD2) in the critical dimension correction map 60.

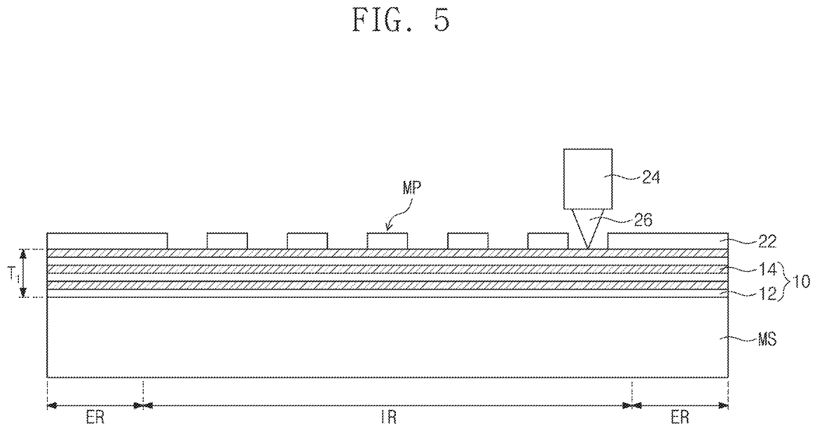

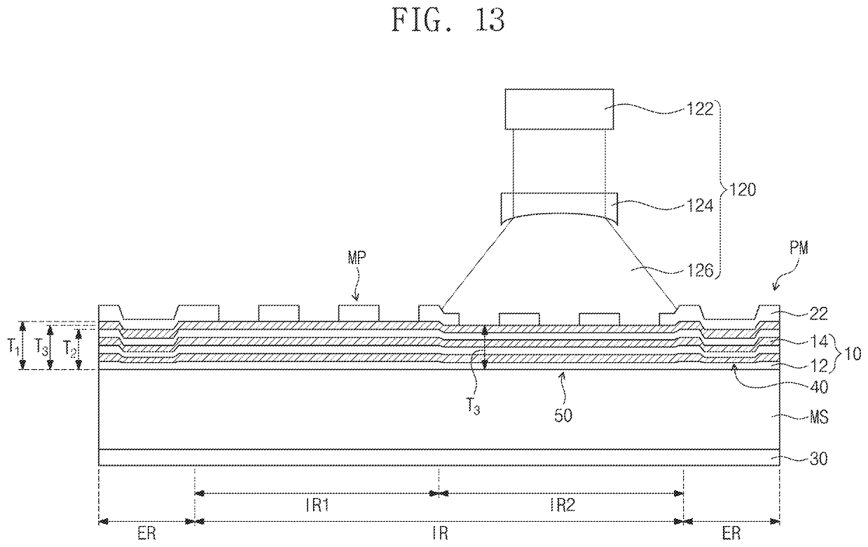

FIG. 13 shows an example of a second laser apparatus 120 that anneals the reflective layer 10 on a portion of the image region IR of FIG. 5.

Referring to FIGS. 2 and 13, the second laser apparatus 120 may provide the reflective layer 10 on a portion of the image region IR with a second laser beam 126 to form an annealing region 50 (S195), also referred to herein as an annealed region. For example, the second laser apparatus 120 may provide the second laser beam 126 onto top surfaces of the reflective layer 10 and the mask pattern MP on a second image region IR2 that corresponds to the correction region 64. The second laser apparatus 120 may include, for example, a second light source 122 and a third optical system 124. The second light source 122 may generate the second laser beam 126 and may provide the third optical system 124 with the second laser beam 126. The third optical system 124 may include a concave lens. The third optical system 124 may provide the second laser beam 126 to a portion of the image region IR. The image region IR may include, for example, a first image region IR1 and a second image region IR2. The first image region IR1 and the second image region IR2 may respectively correspond to the non-correction region 62 and the correction region 64 of the critical dimension correction map 60. The second laser beam 126 may be provided onto the top surfaces of the reflective layer 10 and the mask pattern MP on the second image region IR2. The second laser beam 126 may be different from the first laser beam 116. For example, the second laser beam 126 may be a visible laser beam. The second laser beam 126 may anneal the reflective layer 10 and the mask pattern MP on the second image region IR2, thereby shrinking the reflective layer 10. The reflective layer 10 in the annealing region 50 may have a third thickness T3. The third thickness T3 may be less than the first thickness T1 and greater than the second thickness T2. For example, the reflective layer 10 on the second image region IR2 may have a third thickness T3 of about 240 nm. A reduced reflectance may be given to the reflective layer 10 on the second image region IR2 that corresponds to the correction region 64 of the critical dimension correction map 60. When the reflective layer 10 on the second image region IR2 has a reduced reflectance (e.g., as compared to the reflective layer 10 on the first image region IR1), the EUV beam 202 may decrease in intensity and quantity. When the EUV beam 202 decreases in intensity and quantity, a substrate pattern (see WP of FIG. 20) which will be formed on a substrate (see W of FIG. 20) may have a reduced critical dimension. For example, the second laser beam 126 may anneal the reflective layer 10 on the second image region IR2 that corresponds to the correction region 64, and thus the substrate pattern WP may undergo a reduction correction of the critical dimension.

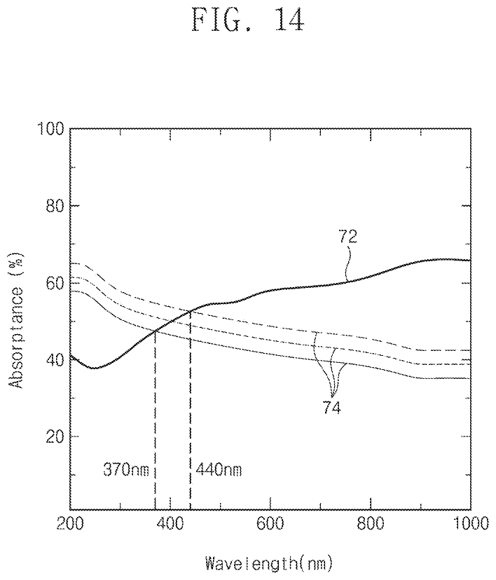

FIG. 14 shows a first absorptance 72 of the reflective layer 10 based on a second wavelength of the second laser beam 126 of FIG. 13, and also shows second absorptances 74 of a structure in which the mask pattern P and the reflective layer 10 are stacked.

Referring to FIG. 14, the first absorptance 72 of the reflective layer 10 exposed from the mask pattern MP may be proportional to a second wavelength of the second laser beam 126, and the second absorptances of the stack structure of the mask pattern MP and the reflective layer 10 may be inversely proportional to a second wavelength of the second laser beam 126. The first absorptance 72 may be an absorptance of the reflective layer 10 with respect to light energy of the second laser beam 126. The second absorptances 74 may correspond to a sum of an absorptance of the mask pattern MP with respect to light energy of the second laser beam 126 and thermal-energy absorptances of the reflective layer 10 and the mask pattern MP. The second absorptances 74 may be changed depending on a refraction difference due to a mixing ratio of compositions (e.g., tantalum (Ta) and boron (B)) of the mask pattern MP.

The second laser apparatus 120 may use a field of the second laser beam 126 (i.e., a field of illumination) having a second wavelength that is different than the first wavelength of the first laser beam 116 (e.g., a second wavelength ranging from about 370 nm to about 440 nm) to anneal the reflective layer 10 flat without stepped portions on the second image region IR2. For example, when the second wavelength of the second laser beam 126 ranges from about 370 nm to about 440 nm, the first and second absorptances 72 and 74 may become identical to each other. When the first and second absorptances 72 and 74 become identical to each other, the reflective layer 10 on the second image region IR2 may be annealed at the same temperature. The annealed reflective layer 10 may be flat without an inclined surface or stepped portion on the second image region IR2. The planarized reflective layer 10 may remove and/or prevent the scattered reflection of the EUV beam 202, such that the substrate pattern WP may increase in critical dimension uniformity. Accordingly, the second laser beam 126 may anneal the reflective layer 10 to be more flat on the second image region IR2 and may improve critical dimension uniformity.

When the first and second absorptances 72 and 74 are different from each other, a typical laser beam may anneal the reflective layer 10 non-flat to cause errors of critical dimension or deterioration of critical dimension uniformity. For example, the typical laser beam may be the first laser beam 116.

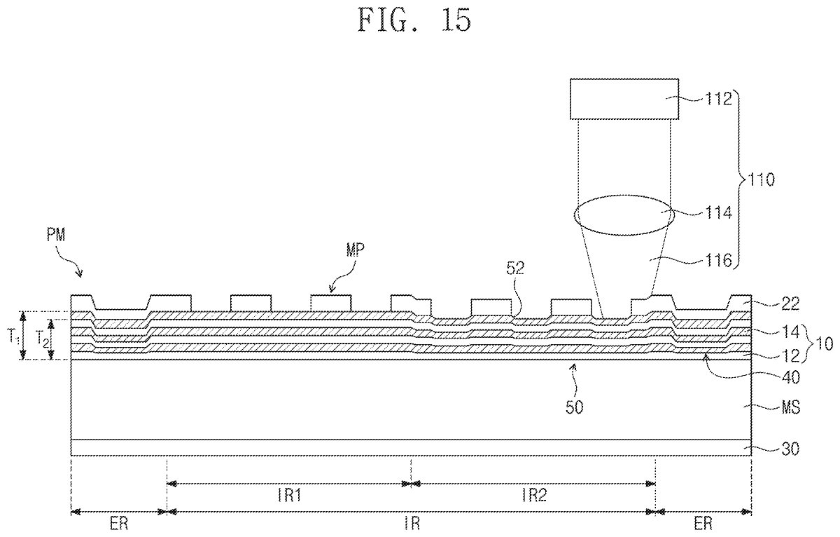

FIG. 15 shows that the first laser beam 116 of the first laser apparatus 110 of FIG. 7 forms an inclined surface 52 of the reflective layer 10 on the annealing region 50.

Referring to FIG. 15, when the first laser apparatus 110 provides the reflective layer 10 on the second image region IR2 with the first laser beam 116 to form the annealing region 50, the first laser beam 116 may form at least one inclined or non-planar surface 52 on the reflective layer 10 adjacent to the absorption pattern 22. The inclined surface 52 may scatter the EUV beam 202 to cause errors of critical dimension correction of the photomask PM. The inclined surface 52 may deteriorate critical dimension uniformity of the substrate pattern WP. Because the first absorptance 72 of the reflective layer 10 with respect to the first laser beam 116 is different from the second absorptances 74 of the stack structure of the reflective layer 10 and the mask pattern MP, the reflective layer 10 on the second image region IR2 may not be annealed flat. The first laser beam 116 may form the inclined surface 52 on the top surface of the reflective layer 10 on the second image region IR2.

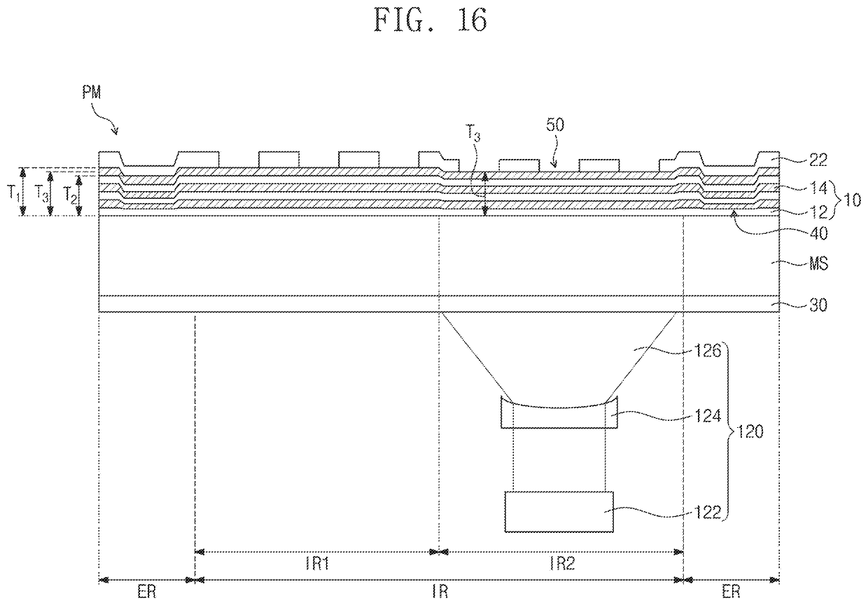

FIG. 16 shows an example of the second laser apparatus 120 that irradiates the second laser beam 126 to the reflective layer 10 of FIG. 3.

Referring to FIGS. 2 and 16, the second laser apparatus 120 may irradiate the second laser beam 126 to the reflective layer 10 on the second image region IR2, thereby forming the annealing region 50 (S195). For example, the second laser beam 126 may be an infrared laser beam. The second laser beam 126 may have a second wavelength that is different than that of the first laser beam 116. The second laser apparatus 120 may force the second laser beam 126 to pass through the lower absorption layer 30 and the mask substrate MS, and thus the second laser beam 126 may be provided to a bottom surface of the reflective layer 10. The reflective layer 10 may be annealed with light energy of the second laser beam 126 that passes through the lower absorption layer 30 and the mask substrate MS. The reflective layer 10 on the annealing region 50 may have the third thickness T3, e.g., of about 240 nm. The reflective layer 10 on the annealing region 50 may be flat without the inclined surface 52. In contrast, the second laser beam 126 may be absorbed into the lower absorption layer 30 to generate thermal energy, which thermal energy may pass through the mask substrate MS to anneal the reflective layer 10. The second laser apparatus 120 may be configured identically to that shown in FIG. 13.

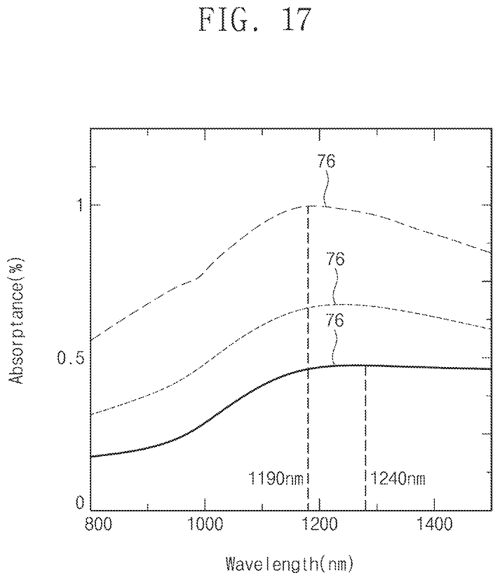

FIG. 17 shows third absorptances 76 with respect to the second laser beam 126 provided to the bottom surface of the reflective layer 10 in FIG. 3.

Referring to FIG. 17, the reflective layer 10 may have the third absorptances 76 with respect to the second laser beam 126 that passes through the lower absorption layer 30 and the mask substrate MS. The third absorptances 76 may be changed depending on a refraction difference due to a mixing ratio of compositions (e.g., tantalum (Ta) and boron (B)) of the lower absorption layer 30. For example, the second laser apparatus 120 may use a field of the second laser beam 126 (i.e., a field of illumination) having a second wavelength ranging from about 1190 nm to about 1240 nm to anneal the reflective layer 10. When the second laser beam 126 has a second wavelength ranging from about 1190 nm to about 1240 nm, the third absorptance 76 of the reflective layer 10 may be increased to the maximum, and annealing efficiency of the second laser beam 126 may be maximized.

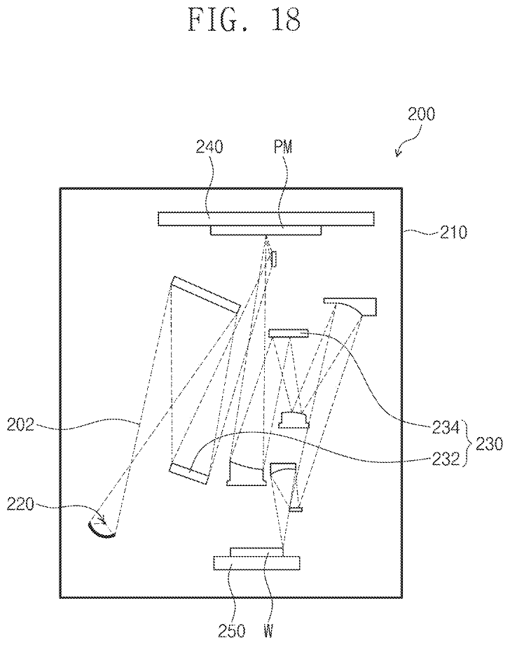

FIG. 18 shows the exposure apparatus 200 to which is loaded the photomask PM having the annealing region 50.

Referring to FIGS. 1 and 18, the exposure apparatus 200 may use the photomask PM having the annealing region 50 to form a photoresist pattern PR on a substrate W (S200). The photomask PM may be disposed on the mask stage 240, and the substrate W may be placed on the substrate stage 250. The chamber 210, the EUV source 220, and the second optical system 230 may be configured identically to those discussed above with reference to FIG. 9. The EUV beam 202 may reflect from the photomask PM, and then may be provided on photoresist on the substrate W. The photoresist may be photosensitized based on the mask pattern MP.

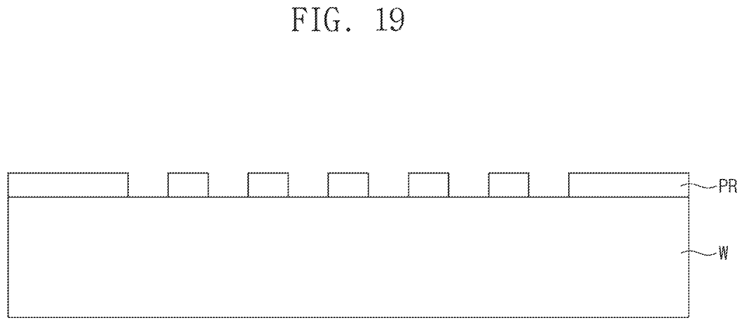

FIGS. 19 and 20 illustrate cross-sectional views showing processes performed on the substrate W of FIG. 18.

Referring to FIG. 19, a spinner apparatus may develop the photosensitized photoresist to form the photoresist pattern PR.

Referring to FIGS. 1 and 20, an etch apparatus may use the photoresist pattern PR as an etching mask to etch the substrate W to form the substrate pattern WP (S300). Afterwards, the photoresist pattern PR may be removed. The substrate pattern WP may have no difference in critical dimension. It may be possible to improve critical dimension uniformity.

As discussed above, a photomask manufacturing method according to some example embodiments of the present inventive concepts may improve critical dimension uniformity of a substrate pattern by providing a reflective layer on an image region of a mask substrate with a second laser beam having a second wavelength different from a first wavelength of a first laser beam irradiated to an edge region of the mask substrate.

Although the present invention has been described in connection with the embodiments of the present invention illustrated in the accompanying drawings, it will be understood to those skilled in the art that various changes and modifications may be made without departing from the technical spirit and essential feature of the present invention. It therefore will be understood that the embodiments described above are just illustrative but not limitative in all aspects.

what is claimed is:

1. A photomask manufacturing method, comprising:
forming a reflective layer on a mask substrate comprising an image region and an edge region surrounding the image region;
forming an absorption pattern on the reflective layer;
irradiating a first laser beam to the reflective layer and the absorption pattern on the edge region to form a black border;
providing an extreme ultraviolet (EUV) beam to a test substrate using a photomask having the black border to form a test pattern;
obtaining a critical dimension correction map based on a critical dimension of the test pattern; and
irradiating a second laser beam to the reflective layer on a portion of the image region using the critical dimension correction map to form an annealed region that is thicker than the black border.

2. The photomask manufacturing method of claim 1, wherein the second laser beam comprises a second wavelength that is different from a first wavelength of the first laser beam.

3. The photomask manufacturing method of claim 2, wherein the portion of the image region is a second portion, and, responsive to the irradiating of the second laser beam, the reflective layer on the second portion of the image region has a second reflectance that is less than a first reflectance thereof on a first portion of the image region.

4. The photomask manufacturing method of claim 2, wherein
the second laser beam is irradiated to a top surface of the reflective layer and to a top surface of the absorption pattern,
the first laser beam comprises an infrared laser beam, and
the second laser beam comprises a visible laser beam.

5. The photomask manufacturing method of claim 4, wherein
the first wavelength is about 980 nm, and
the second wavelength ranges from about 370 nm to about 440 nm.

6. The photomask manufacturing method of claim 2, further comprising forming a lower absorption layer on a bottom surface of the mask substrate prior to the irradiating of the second laser beam.

7. The photomask manufacturing method of claim 6, wherein
the second laser beam passes through the lower absorption layer and the mask substrate and is irradiated to a bottom surface of the reflective layer, and
each of the first and second laser beams comprises a respective infrared laser beam.

8. The photomask manufacturing method of claim 7, wherein the second wavelength is longer than the first wavelength.

9. The photomask manufacturing method of claim 8, wherein
the first wavelength is about 980 nm, and
the second wavelength ranges from about 1190 nm to about 1240 nm.

10. The photomask manufacturing method of claim 1, wherein
the reflective layer has a first thickness,
the black border has a second thickness that is less than the first thickness, and
the annealed region has a third thickness that is less than the first thickness and is greater than the second thickness.

11. A photomask manufacturing method, comprising:
forming a reflective layer on a mask substrate comprising an image region and an edge region surrounding the image region;
forming an absorption pattern on the mask substrate;
irradiating a first laser beam to the absorption pattern and the reflective layer on the edge region to form a first annealed region; and
irradiating a second laser beam to the reflective layer on the image region to form a second annealed region that is thicker than the first annealed region.

12. The photomask manufacturing method of claim 11, further comprising:
providing an extreme ultraviolet (EUV) beam to a test substrate using a photomask having the first annealed region to form a test pattern;
inspecting the test pattern to acquire a critical dimension of the test pattern; and
obtaining a critical dimension correction map based on the critical dimension of the test pattern.

13. The photomask manufacturing method of claim 12, wherein the critical dimension correction map comprises a non-correction region of the critical dimension and a correction region of the critical dimension.

14. The photomask manufacturing method of claim 13, wherein the image region comprises a first image region and a second image region that correspond to the non-correction region of the critical dimension and the correction region of the critical dimension, respectively.

15. The photomask manufacturing method of claim 14, wherein the second laser beam is irradiated to the second image region, and wherein, responsive to the irradiating of the second laser beam, the reflective layer on the second image region has a second reflectance that is less than a first reflectance thereof on the first image region.

16. A semiconductor device fabrication method, comprising:
manufacturing a photomask;
forming a photoresist pattern on a substrate using the photomask; and
etching a portion of the substrate using the photoresist pattern as an etching mask,
wherein manufacturing the photomask comprises:
forming a reflective layer on a mask substrate comprising an image region and an edge region surrounding the image region;
forming an absorption pattern on the reflective layer;
irradiating a first laser beam to the reflective layer and the absorption pattern on the edge region to form a black border;
providing an extreme ultraviolet (EUV) beam to a test substrate using the photomask having the black border to form a test pattern;
obtaining a critical dimension correction map based on a critical dimension of the test pattern; and
irradiating a second laser beam to the reflective layer on a portion of the image region using the critical dimension correction map to form an annealed region that is thicker than the black border.

17. The semiconductor device fabrication method of claim 16, wherein forming the photoresist pattern on the substrate using the photomask comprises:
reflecting the extreme ultraviolet (EUV) beam toward the photomask to photosensitize a photoresist on the substrate; and
developing the photoresist that was photosensitized to form the photoresist pattern.

18. The semiconductor device fabrication method of claim 16, wherein forming the reflective layer comprises:
forming a structure in which a semiconductor layer and a metal layer are alternately stacked,
wherein the reflective layer on the portion of the image region has a first reflectance prior to the irradiating of the second laser beam and a second reflectance responsive to the irradiating of the second laser beam, wherein the second reflectance is less than the first reflectance.

19. The semiconductor device fabrication method of claim 18, wherein
the semiconductor layer comprises a silicon layer, and
the metal layer comprises a molybdenum layer.

20. The semiconductor device fabrication method of claim 16, wherein the absorption pattern comprises metal nitride.
